(19) United States
(12) Patent Application Publication
(10) Pub. No.: US 2009/0288873 A1
(43) Pub. Date: Nov. 26, 2009

(54) WIRING BOARD AND METHOD OF MANUFACTURING THE SAME

(75) Inventors: Akio HORIUCHI, Nagano-shi (JP); Kazuhiro OSHIMA, Nagano-shi (JP)

Correspondence Address: DRINKER BIDDLE & REATH (DC), 1500 K STREET, N.W., SUITE 1100, WASHINGTON, DC, 20005-1209, US

(73) Assignee: Shinko Electric Inudustries Co., Ltd., Nagano-shi (JP)

(21) Appl. No.: 12/470,083

(22) Filed: May 21, 2009

(30) Foreign Application Priority Data
May 23, 2008 (JP) 2008-135031

(51) Int. Cl. H01R 12/04; H05K 3/36

(52) U.S. Cl. 174/262; 29/830

(57) ABSTRACT

A wiring board is provided. The wiring board includes: a resin substrate having a through-hole therethrough; metal foil patterns formed on the resin substrate; and a first wiring layer formed on the metal foil patterns and on an inner surface of the through-hole, wherein the first wiring layer includes: a first power feeding layer; and a first plated layer laminated on the first power feeding layer; a resin member filled in the through-hole and between adjacent wiring patterns of the first wiring layer, wherein an end surface of the resin member is flush with a surface of the first wiring layer; and a second wiring layer formed on the surface of the first wiring layer and formed to cover an end surface of the through-hole, wherein the second wiring layer includes: a second power feeding layer; and a second plated layer laminated on the second power feeding layer.

This application claims priority from Japanese Patent Application No. 2008-13 5031, filed on May 23, 2008, the entire contents of which are hereby incorporated by reference.

### BACKGROUND OF THE INVENTION

1. Technical Field

The present disclosure relates to a wiring board and a method of manufacturing the same.

2. Related Art

Along with high density and high speed of semiconductor devices, wiring patterns are extremely finely formed on a wiring board for mounting electronic components such as a semiconductor elements.

The wiring board includes a through-hole to electrically connect respective wiring layers formed on both surfaces of the wiring board, and the respective wiring layers formed on both surfaces are electrically connected to each other via a conductor layer formed on an inner surface of the through-hole.

For example, JP-A-2006-287085 describes a method of manufacturing the above wiring board. In JP-A-2006-287085, first of all, a through-hole is formed to pass through a glass epoxy board on both surfaces of which metal foil is laminated, then a conductive layer is formed on the entire surface of the board, including an inner surface of the through-hole, and then the conductive layer is etched away to form wiring patterns on the both surfaces of the board.

Also, as a wiring board of a semiconductor device for realizing higher density and higher speed, there has been also proposed a wiring board on which an electronic component can be mounted even directly above a through-hole in order to enlarge an area for mounting electronic components on the wiring board. Such a wiring board includes a plated cover serving as a conductor layer, which is formed directly above the through-hole.

In JP-A-2006-287085, wiring patterns are formed using a so-called subtractive method when the wiring patterns are formed on the surface of the board. However, the subtractive method has a problem in that the wiring patterns cannot be formed sufficiently finely since a wiring pitch between the wiring patterns depends on the thickness of the conductor layer.

That is, in order to form a fine wiring pattern by the subtractive method, it is necessary to thinly form the conductor layer. However, when the thickness of the conductor layer is reduced to form the fine wiring pattern, the method has a problem in that the thickness of the conductor layer formed on the inner surface of the through-hole is also reduced and thus the reliability of the electrical connection by the through-hole decreases. Particularly, since the thickness of the conductor layer is reduced at a position near an opening portion of the through-hole, the method has a problem in that the electrical connection between the conductor layer and the wiring becomes unstable.

Moreover, the wiring pattern formed by the subtractive method has problems in that dimension errors of the wiring are increased and the impedance characteristic of the wiring pattern in the same layer is decreased.

### SUMMARY OF THE INVENTION

Exemplary embodiments of the present invention address the above disadvantages and other disadvantages not described above. However, the present invention is not required to overcome the disadvantages described above, and thus, an exemplary embodiment of the present invention may not overcome any of the problems described above.

Accordingly, it is an aspect of the present invention to provide a wiring board having a through-hole and a method for manufacturing the same. According to the wiring board and the method of manufacturing the same, a fine wiring pattern can be formed on both surfaces of the wiring board and the impedance characteristic of the wiring pattern in the same layer can be improved without decreasing the connection reliability of the wiring pattern adjacent to an inner surface of the through-hole.

According to one or more aspects of the present invention, a wiring board is provided. The wiring board comprises: a resin substrate having a through-hole therethrough; metal foil patterns formed on the resin substrate; a first wiring layer formed on the metal foil patterns and on an inner surface of the through-hole, the first wiring layer comprising: a first power feeding layer; and a first plated layer laminated on the first power feeding layer; a resin member filled in the through-hole and between adjacent wiring patterns of the first wiring layer, wherein an end surface of the resin member is flush with a surface of the first wiring layer; and a second wiring layer formed on the surface of the first wiring layer and formed to cover an end surface of the through-hole, the second wiring layer comprising: a second power feeding layer; and a second plated layer laminated on the second power feeding layer.

According to one or more aspects of the present invention, there is provided a method of manufacturing a wiring board. The method comprises: (a) forming a through-hole in a resin substrate, wherein a metal foil is formed on both surfaces of the resin substrate; (b) forming a first power feeding layer on the metal foil and an inner surface of the through-hole; (c) forming a first plating mask on the first power feeding layer; (d) forming a first plated layer on the first power feeding layer by using the first plating mask; (e) removing the first plating mask; (f) removing portions of the first power feeding layer and the metal foil that are exposed from the first plated layer, thereby forming a first wiring layer; (g) covering surfaces of the resin substrate and the first wiring layer with a resin member while filling an inner space of the through-hole with the resin member; (h) grinding the resin member such that the surface of the first wiring layer is flush with a surface of the resin member; (i) forming a second power feeding layer on the surfaces of the first wiring layer and the resin member; (j) forming a second plating mask on the second power feeding layer; (k) forming a second plated layer on the second power feeding layer by using the second plating mask; (l) removing the second plating mask; and (m) removing a portion of the second power feeding layer that is exposed from the second plating mask, thereby forming a second wiring layer.

Other aspects and advantages of the invention will be apparent from the following description, the drawings and the claims.

### BRIEF DESCRIPTION OF THE DRAWINGS

FIGS. 1A to 1C are sectional views illustrating a first process to a third process in a method for manufacturing a wiring board according to a first exemplary embodiment;

FIGS. 2A to 2C are sectional views illustrating a fourth process to a sixth process in the method for manufacturing the wiring board according to the first exemplary embodiment;

FIGS. 3A to 3C are sectional views illustrating a seventh process to a ninth process in the method for manufacturing the wiring board according to the first exemplary embodiment;

FIGS. 4A to 4C are sectional views illustrating a tenth process to a twelfth process in the method for manufacturing the wiring board according to the first exemplary embodiment;

FIGS. 5A and 5B are sectional views illustrating a thirteenth process to a fourteenth process in the method for manufacturing the wiring board according to the first exemplary embodiment;

FIGS. 6A and 6B are sectional views illustrating a method for manufacturing a wiring board according to a second exemplary embodiment;.

FIGS. 7A and 7B are sectional views illustrating the method for manufacturing the wiring board according to the second exemplary embodiment;

FIGS. 8A and 8B are sectional views illustrating the method for manufacturing the wiring board according to the second exemplary embodiment;

FIGS. 9A to 9C are sectional views illustrating a method for manufacturing a wiring board according to a third exemplary embodiment;

FIGS. 10A to 10C are sectional views illustrating the method for manufacturing the wiring board according to the third exemplary embodiment; and

FIG. 11 is a sectional view illustrating the wiring board obtained using the method for manufacturing the wiring board according to the third exemplary embodiment.

### DETAILED DESCRIPTION OF EXEMPLARY EMBODIMENTS OF THE INVENTION

Exemplary embodiments of the present invention will be described with reference to the drawings.

### First Exemplary Embodiment

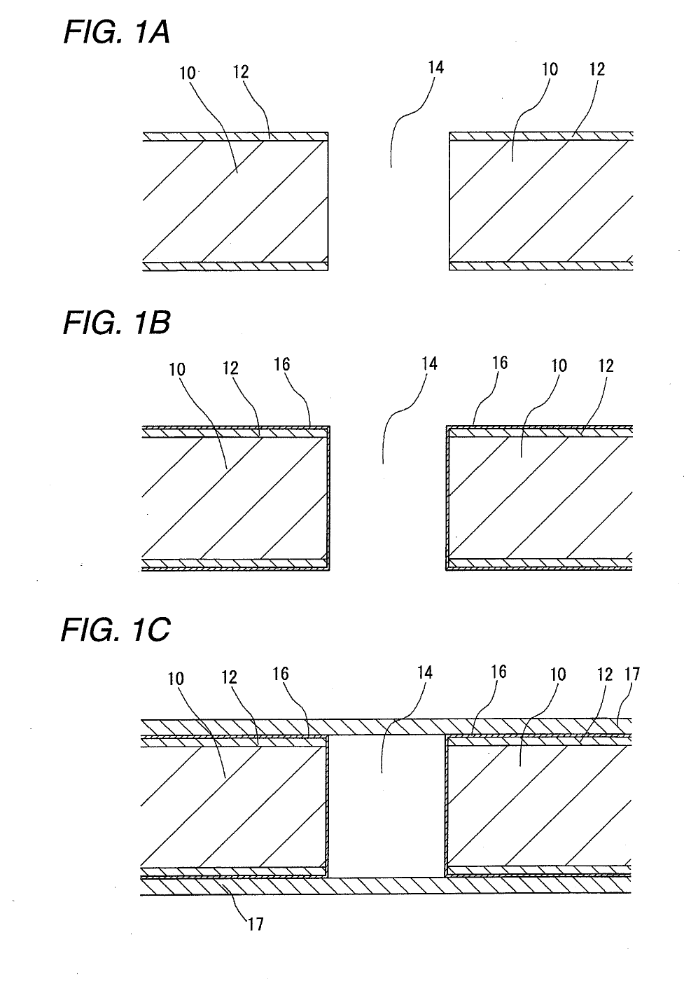

FIGS. 1A to 5B are sectional views illustrating the respective steps in a method for manufacturing a wiring board according to the first exemplary embodiment.

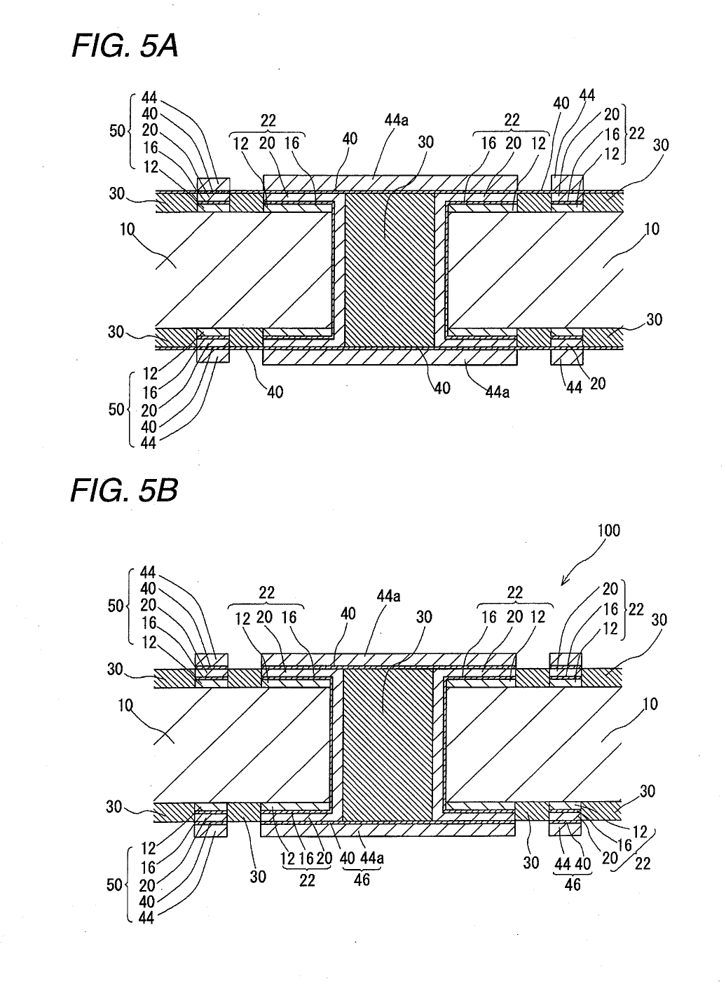

As illustrated in FIG. 5B, in a wiring board 100 according to the present embodiment, wiring layers 50 are formed on both surfaces of a resin substrate 10, a through-hole is formed to penetrate the resin substrate 10, a copper foil 12 of metal foil is laminated on both of the surfaces of the resin substrate 10. Also, a plated covers 44a are formed on the resin substrate 10 to cover the through-hole filled with a resin 30. The wiring layers 50 formed on the upper and lower surfaces of the resin substrate 10 acting as a support are electrically connected to each other through a conductor layer (an electroless copper plated film 16 and an electrolytic copper plated layer 20) formed in the through-hole. The plated cover 44a and the wiring layer 50 according to the present embodiment are formed by a semi-additive method.

Hereinafter, the method of manufacturing the wiring board 100 according to the present embodiment will be described with reference to the drawings.

First of all, as illustrated in FIG. 1A, the resin substrate 10 on both surfaces of which the copper foil 12 is laminated is prepared, and a through-hole 14 is formed to pass through the copper foil 12 and the resin substrate 10 in the through-thickness direction (a first process). In resin substrate 10 of the present embodiment, the copper foils 12 whose thickness is about 3 to 30 μm are laminated on both surfaces thereof. For example, the through-hole 14 can be formed by means of a drill processing.

Next, as illustrated in FIG. 1B, an electroless copper plated film 16 acting as a first power feeding layer is formed on the surface of the copper foil 12 and the inner surface of the through-hole 14 (a second process). In the present embodiment, the thickness of the electroless copper plated film 16 is about 3 μm, for example. The electroless copper plated film 16 is formed as the first power feeding layer in the present embodiment, but another film forming method such as a copper sputtering method may be employed to form the first power feeding layer.

After forming the electroless copper plated film 16, a resist film 17 is entirely coated on the both surfaces of the resin substrate 10 (a third process). Although it has been described that the resist film 17 made of photosensitive resin is used in the present embodiment, a photosensitive liquid resist can also be used instead of the resist film 17. FIG. 1C illustrates a state in which the resist films 17 are laminated to cover the opening parts of the through-hole 14.

After the resist film 17 is laminated, the resist film 17 is exposed and developed by using a pattern mask for forming a plated pattern and an exposure apparatus, and then a plating resist 18 is formed on the surface of the electroless copper plated film 16 (a fourth process). After the plating resist 18 is formed, electrolytic copper plating is performed using the electroless copper plated film 16 as a power feeding layer, and the electrolytic copper plated layer 20 acting as a first plated layer is formed on opening portions of the plating resist 18 and the inner surface of the through-hole 14 (a fifth process).

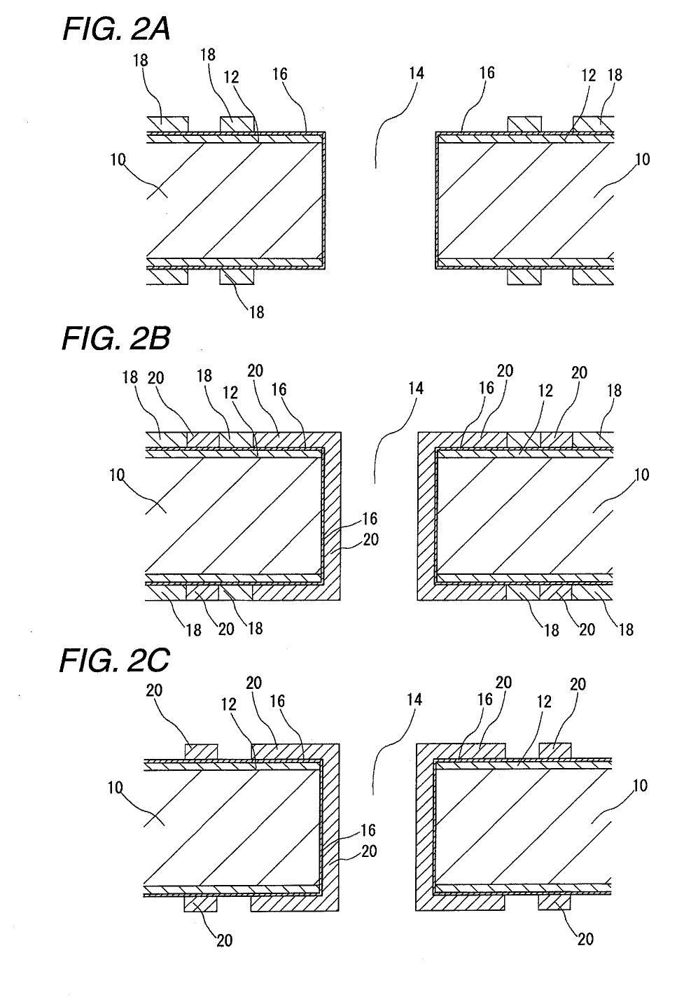

After the electrolytic copper plated layer 20 is deposited to have a given thickness, the plating resist 18 is removed as illustrated in FIG. 2C (a sixth process). The plating resist 18 can be removed by wet etching in which etching solution is used or dry etching.

In this way, it is possible to simultaneously form a plated layer consisting of the electroless copper plated film 16 and the electrolytic copper plated layer 20 on the inner surface of the through-hole 14 and a first wiring layer 22 (the copper foil 12, the electroless copper plated film 16, and the electrolytic copper plated layer 20) that constitutes a part of the wiring layer 50. Accordingly, it is possible to ensure the thickness of the first wiring layer 22 (the copper foil 12, the electroless copper plated film 16, and the electrolytic copper plated layer 20) around the opening portion of the through-hole 14, and thus it is possible to ensure the reliability of the electrical connection around the opening portion of the through-hole 14.

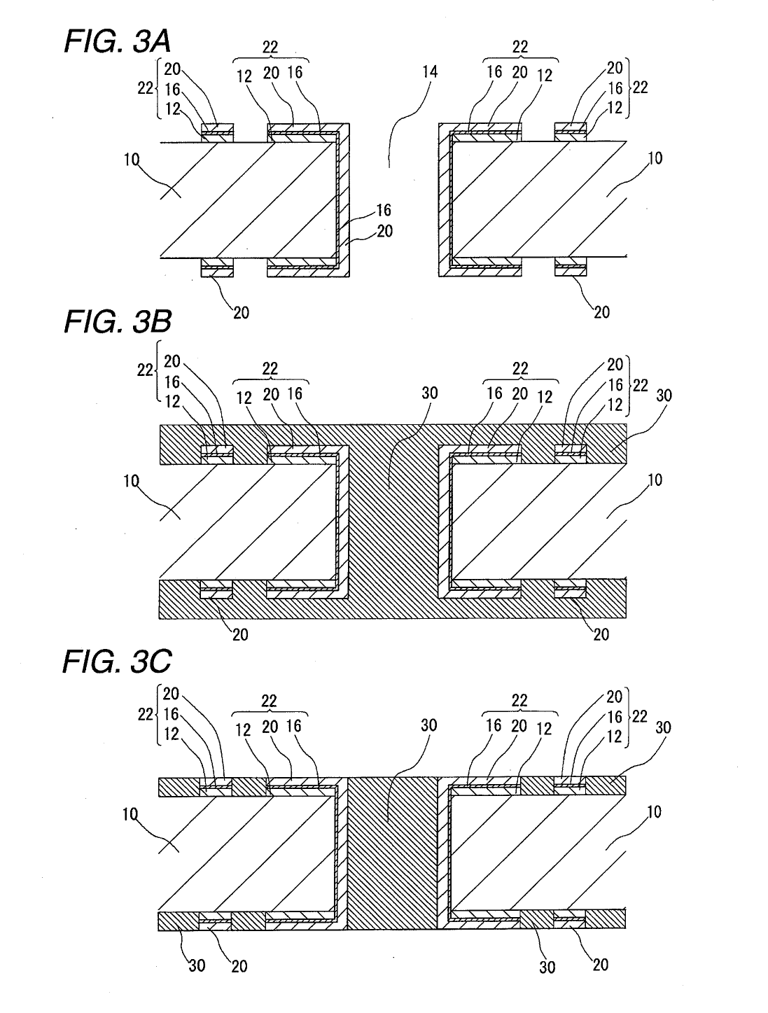

Next, as illustrated in FIG. 3A, the electroless copper plated film 16 and the copper foil 12 that are covered with the plating resist 18 are removed (a seventh process). Since all of the electrolytic copper plated layer 20, the electroless copper plated film 16, and the copper foil 12 are made of copper, the electrolytic copper plated layer 20 is also etched away and becomes slightly thin when the electroless copper plated film 16 and the copper foil 12 are etched away.

Next, as illustrated in FIG. 3B, the resin 30 is formed to cover the both surfaces of the resin substrate 10 so as to fill in the internal space of the through-hole 14 and cover the conductor layers to be wiring patterns (an eighth process). For example, a so-called print process using a squeegee or the like, a method of laminating a resin film on the both surfaces of the resin substrate 10 may be used as a method of coating the resin 30.

Subsequently, as illustrated in FIG. 3C, the resin 30 is ground to the extent that the upper surface of the electrolytic copper plated layer 20 is exposed (a ninth process). For example, it is advantageous to use a Chemical Mechanical Polishing (CMP) method to grind the resin 30. The ground surface can be formed such that the resin 30 is flush with the first wiring layer 22 (the copper foil 12, the electroless copper plated film 16, and the electrolytic copper plated layer 20), which constitutes a part of the wiring layer 50. An amount of the ground resin 30 can also be adjusted so that the thickness of the first wiring layer 22 constituting a part of the wiring layer 50 can become a given thickness. The resin 30 is ground on the upper and lower surfaces as illustrated in FIG. 3C.

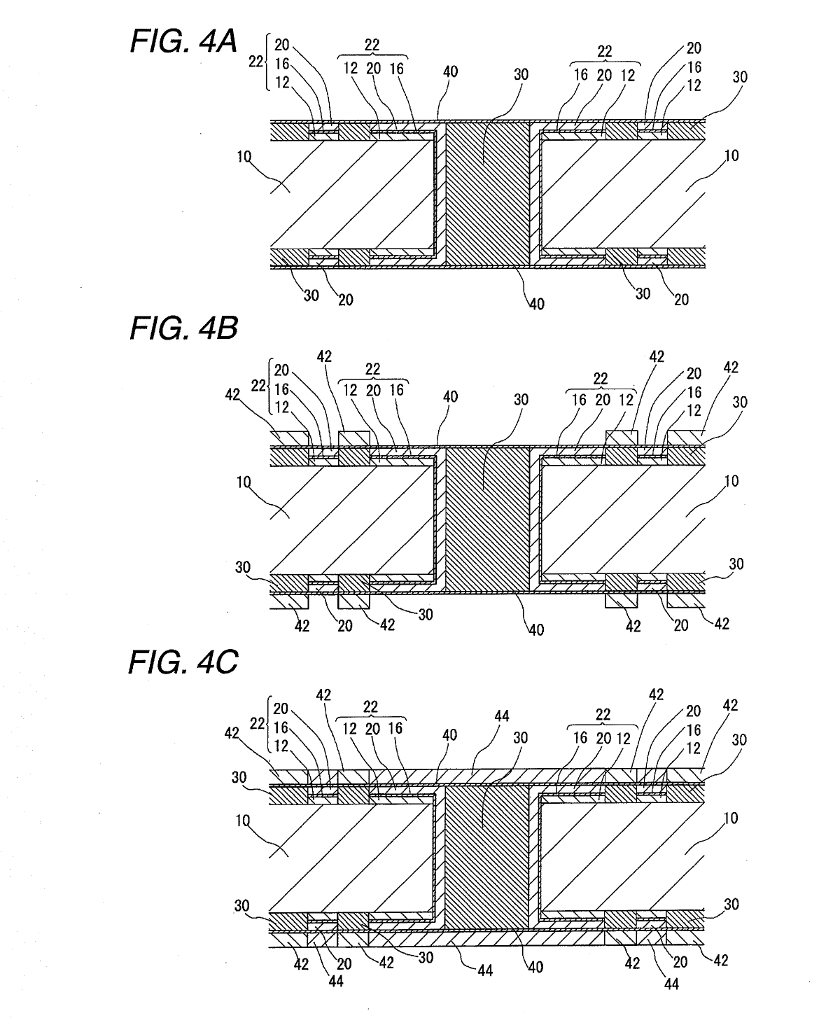

Next, as illustrated in FIG. 4A, an electroless copper plated film 40 acting as a second power feeding layer is formed on each ground surface processed to a flat surface (a tenth process). Similarly to the first power feeding layer, the second power feeding layer can also be formed using any film forming method other than the electroless copper plating method.

Next, as illustrated in FIG. 4B, a plating resist 42 is formed on the electroless copper plated film 40 (an eleventh process). Similarly to the above-described plating resist 18 which is formed on the electroless copper plated film 16 acting as the first power feeding layer, the plating resist 42 can be formed using the method in which a photosensitive resist film is laminated, exposed, and developed. As described above, a photosensitive liquid resist can also be used instead of the photosensitive resist film 17.

The plating resist 42 is formed such that the end faces of the resin member 30 are coated with an electrolytic copper plated layer 44. Moreover, the plating resist 42 is also formed to have the same pattern as the lower layer portion of the wiring pattern 50.

After forming the plating resist 42, the electrolytic copper plated layer 44 acting as a second plated layer is formed (a twelfth process). As illustrated in FIG. 4C, the electrolytic copper plated layer 44 is deposited to have a given thickness.

After forming the electrolytic copper plated layer 44, the plating resist 42 is removed (a thirteenth process).

As illustrated in FIG. 5A, the plating resist 42 is removed to form the plated cover 44a for covering the opening portion of the through-hole 14 and the upper layer portion 44 of the wiring pattern (a fourteenth process). At this point, the plated cover 44a and the upper layer portion 44 of the wiring pattern are electrically short-circuited by the electroless copper plated film 40.

Subsequently, since the electroless copper plated film 40 acting as the second power feeding layer is removed (FIG. 5B: a fifteenth process), a second wiring layer 46 and the plated cover 44a can be formed as a separate pattern, and thus the wiring board 100 that includes the wiring layer 50 composed of the first wiring layer 22 and the second wiring layer 46 can be obtained. It is advantageous that the thickness of the plated cover 44a is 5 μm or more.

According to the manufacturing method of the present embodiment, the plated layer formed on the inner surface of the through-hole 14 and the first power feeding layer 16 of the first wiring layer 22 can be simultaneously formed. Thus, the manufacturing processes can be shortened compared to the conventional manufacturing method. Moreover, since the wiring layer 50 formed on the surface of the wiring board 100 can be formed using a semi-additive method, a wiring pattern can be formed to have fine intervals as compared with the conventional subtractive method. Furthermore, since size fluctuations between the wiring patterns can be greatly reduced, the impedance characteristic of the wiring pattern on the same wiring layer can be uniformed, and thus the wiring board 100 having through-hole therein can have excellent electrical characteristics.

### Second Exemplary Embodiment

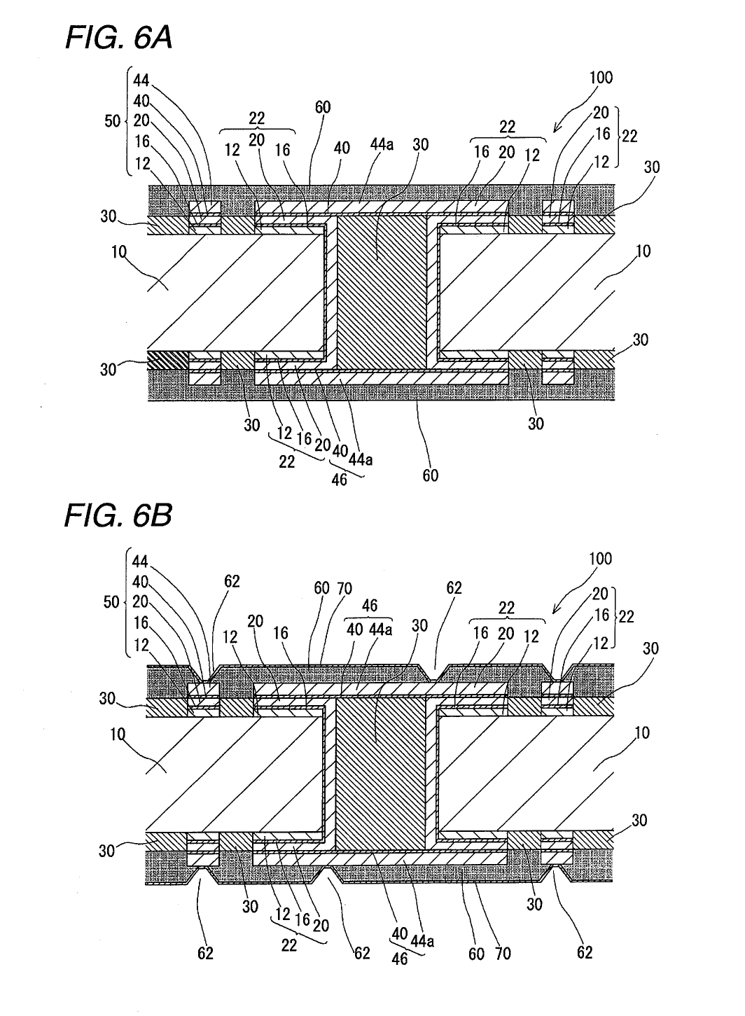

Although only one layer is formed on the both surfaces of the resin substrate 10 in the wiring pattern 50 of the wiring board 100 in the first exemplary embodiment, the wiring layer can be laminated on each of the upper and lower surfaces of the wiring board illustrated in FIG. 5B by means of a buildup method. In the present embodiment, there will be described a wiring board manufacturing method when the multilayer wiring layer 50 is formed on the wiring board 100 of the first exemplary embodiment by means of the buildup method. FIGS. 6A to 8B are sectional views illustrating the respective manufacturing processes of the wiring board according to the second exemplary embodiment.

First, as illustrated in FIG. 6A, a resin film is laminated on both surfaces of the wiring board 100, thereby forming an insulating layer 60 (a sixteenth process). After forming the insulating layer 60, a via hole 62 is formed in the insulating layer 60 (a seventeenth process). The via hole 62 is formed by irradiating the insulating layer with a laser. After forming the via hole 62, an electroless copper plated film 70 is formed on the surface of the insulating layer 60 as a third power feeding layer (FIG. 6B: an eighteenth process).

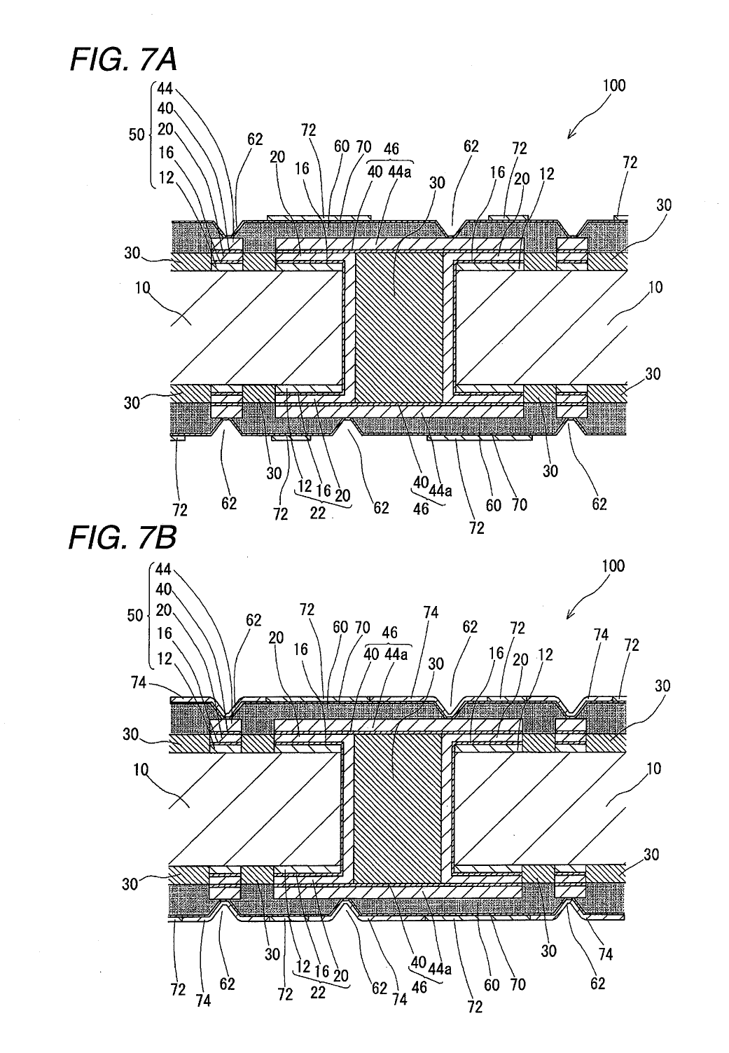

Next, as illustrated in FIG. 7A, a plating resist 72 having a given pattern is formed on the surface of the electroless copper plated film 70 (a nineteenth process). The plating resist 72 can also be formed similarly to the method for forming the plating resist 18 and 42 according to the first exemplary embodiment.

Next, as illustrated in FIG. 7B, an electrolytic copper plated layer 74 acting as a third plated layer is deposited on the surface of the electroless copper plated film 70 using the electroless copper plated film 70 as a power feeding plated layer (a twentieth process).

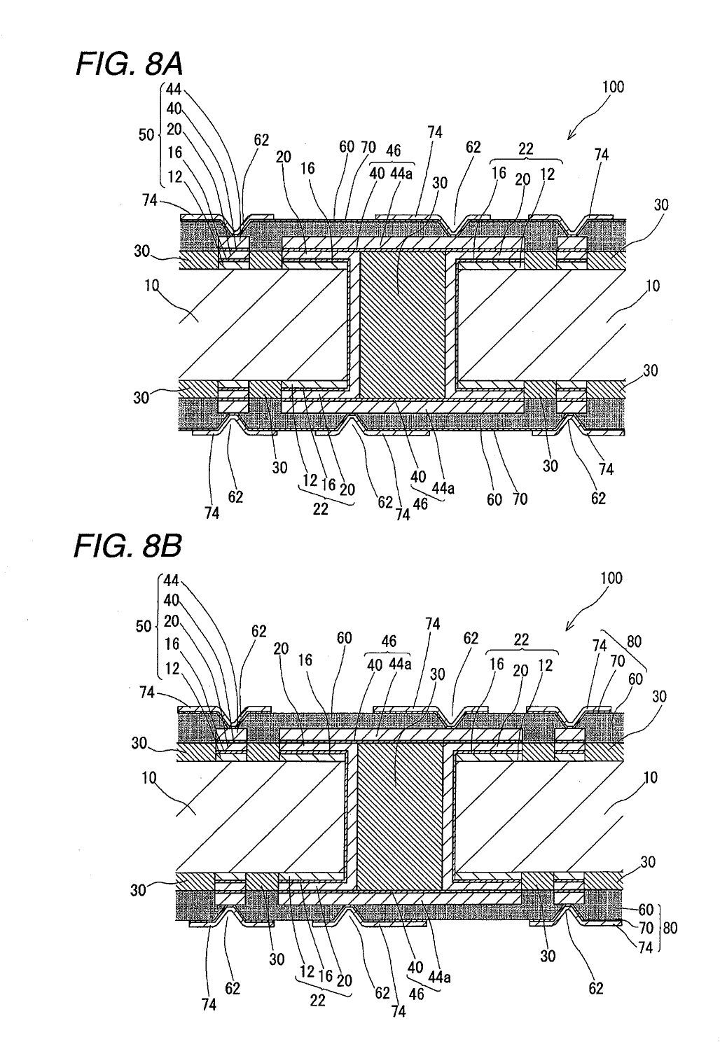

After the electrolytic copper plated layer 74 is deposited to have a given thickness, the plating resist 72 is removed (FIG. 8A: a twenty-first process), and the exposed portion of the electroless copper plated film 70 acting as the third power feeding layer is removed (FIG. 8B: a twenty-second process).

FIG. 8B illustrates a state in which an upper wiring layer 80 is formed to be electrically connected to a lower wiring layer 50 via the insulating layer 60. The upper wiring layer 80 can be formed to have a further multilayer configuration by repeatedly performing the forming process of the upper wiring pattern 80 (the sixteenth process to the twenty-second process).

### Third Exemplary Embodiment

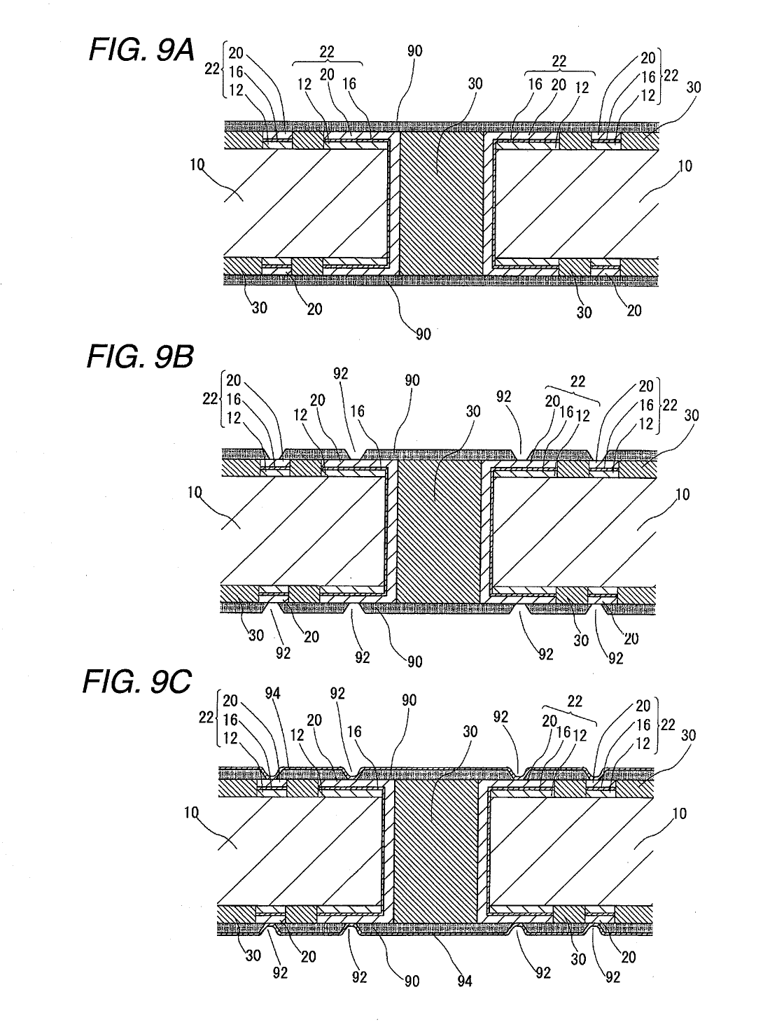

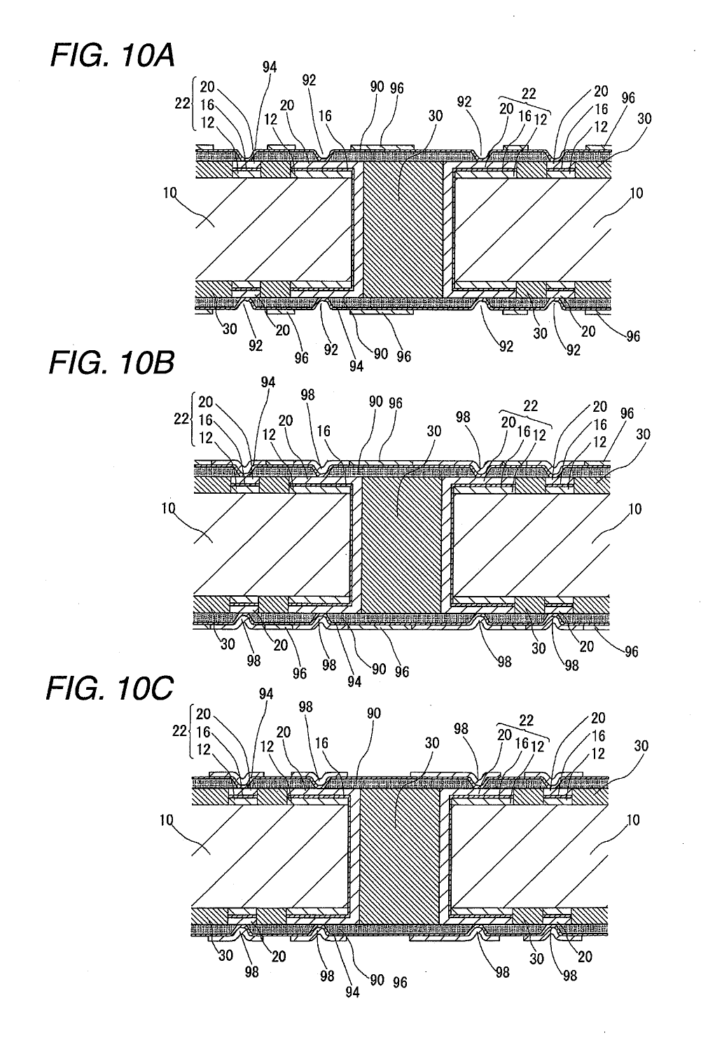

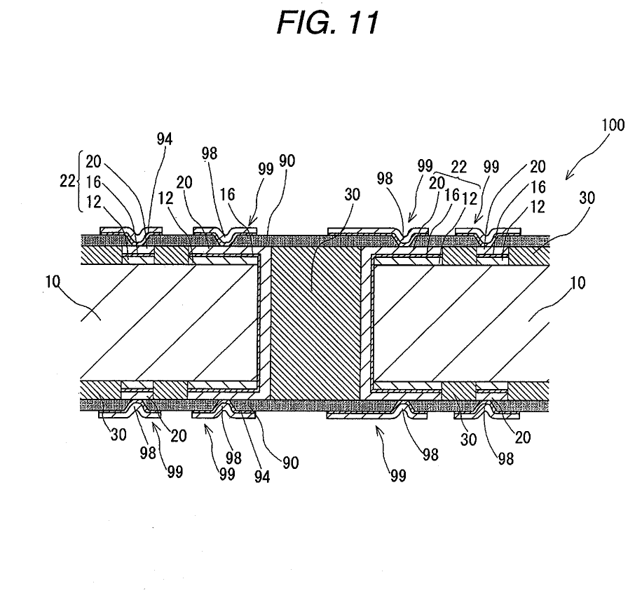

According to the method for manufacturing the wiring board 100 as described above, the electrolytic copper plated layer 20 acting as the first plated layer and the resin 30 are ground to be flush with each other as illustrated in FIG. 3C and then the wiring layer 50 and the plated cover 44a are formed by the semi-additive method with the ground face as a reference face as illustrated in FIG. 4A. However, after the process illustrated in FIG. 3C, the wiring board 100 (see FIG. 11) formed with a buildup wiring layer 99 can be obtained through the processes illustrated in FIGS. 9A to 10C. That is, first of all, a buildup resin 90 acting as an insulating layer is laminated to the ground surface (FIG. 9A); a via hole 92 is formed in the buildup resin 90 (FIG. 9B); a power feeding layer 94 (an electroless copper plated film, a copper sputtering film or the like) is formed on the surfaces of the buildup resin 90 and the via hole 92 (FIG. 9C); a plating resist 96 is formed on the power feeding layer 94 (FIG. 10A); an electrolytic copper plated layer 98 is formed using the plating resist 96 (FIG. 10B), the plating resist 96 is removed (FIG. 10C); and then the exposed power feeding layer 94 is removed.

Moreover, the upper buildup wiring layer, which is electrically connected to the buildup wiring layer 99 via the insulating layer (buildup resin), can also be laminated to have a single layer or multiple layers on the buildup wiring layer 99.

While the present invention has been shown and described with reference to certain example embodiments, other implementations are within the scope of the claims. It will be understood by those skilled in the art that various changes in form and details may be made therein without departing from the spirit and scope of the invention as defined by the appended claims.

What is claimed is:

1. A wiring board comprising:
a resin substrate having a through-hole therethrough;
metal foil patterns formed on the resin substrate;
a first wiring layer formed on the metal foil patterns and on an inner surface of the through-hole, the first wiring layer comprising: a first power feeding layer; and a first plated layer laminated on the first power feeding layer;
a resin member filled in the through-hole and between adjacent wiring patterns of the first wiring layer, wherein an end surface of the resin member is flush with a surface of the first wiring layer; and
a second wiring layer formed on the surface of the first wiring layer and formed to cover an end surface of the through-hole, the second wiring layer comprising: a second power feeding layer; and a second plated layer laminated on the second power feeding layer.

2. The wiring board of claim 1, further comprising:
an insulating layer formed to cover the second wiring layer and a portion of the resin member formed between the adjacent wiring patterns of the first wiring layer; and
a third wiring layer formed on the insulating layer to be electrically connected to the second wiring layer via the insulating layer.

3. The wiring board according to claim 1, wherein a portion of the second wiring layer covering the end surface of the through-hole has a thickness of 5 μm or more.

4. A method of manufacturing a wiring board, the method comprising:
(a) forming a through-hole in a resin substrate, wherein a metal foil is formed on both surfaces of the resin substrate;
(b) forming a first power feeding layer on the metal foil and an inner surface of the through-hole;
(c) forming a first plating mask on the first power feeding layer;
(d) forming a first plated layer on the first power feeding layer by using the first plating mask;
(e) removing the first plating mask;
(f) removing portions of the first power feeding layer and the metal foil that are exposed from the first plated layer, thereby forming a first wiring layer;
(g) covering surfaces of the resin substrate and the first wiring layer with a resin member while filling an inner space of the through-hole with the resin member;
(h) grinding the resin member such that the surface of the first wiring layer is flush with a surface of the resin member;
(i) forming a second power feeding layer on the surfaces of the first wiring layer and the resin member;
(j) forming a second plating mask on the second power feeding layer;
(k) forming a second plated layer on the second power feeding layer by using the second plating mask;
(l) removing the second plating mask; and
(m) removing a portion of the second power feeding layer that is exposed from the second plating mask, thereby forming a second wiring layer.

5. The method according to claim 4, wherein step (k) comprises:
forming a plated cover that covers an end surface of the resin member filled in the inner space of the through-hole.

6. The method according to claim 4, further comprising:
(n) covering surfaces of the second wiring layer and the resin member; and
(o) forming a third wiring layer on the insulating layer such that the third wiring layer is electrically connected to the second wiring layer via the insulating layer.
